(19) United States
(12) Patent Application Publication
(10) Pub. No.: US 2020/0262029 A1
(43) Pub. Date: Aug. 20, 2020

(54) GRINDING APPARATUS

(71) Applicant: DISCO CORPORATION, Tokyo (JP)

(72) Inventors: Shungo YOSHII, Tokyo (JP); Souichi MATSUBARA, Tokyo (JP); Nobuyuki FUKUSHI, Tokyo (JP); Hidekazu NAKAYAMA, Tokyo (JP)

(21) Appl. No.: 16/791,366

(22) Filed: Feb. 14, 2020

(30) Foreign Application Priority Data
Feb. 20, 2019 (JP) 2019-028372

(51) Int. Cl. B24B 55/06; B24B 7/04; H01L 21/304; H01L 21/683; B24B 7/22; B24B 41/00; B24B 41/06

(52) U.S. Cl. CPC B24B 55/06; B24B 7/04; H01L 21/304; B24B 41/06; B24B 7/228; B24B 41/005; H01L 21/683

(57) ABSTRACT

A grinding apparatus includes a loading unit for loading a wafer to a chuck table having a holding surface for holding the wafer, an unloading unit for unloading the wafer from the chuck table, and a cleaning unit for cleaning the holding surface of the chuck table or the upper surface of the wafer held on the holding surface of the chuck table. The cleaning unit includes a cleaning portion and a horizontal moving portion for horizontally moving the cleaning portion in a lateral direction of the grinding apparatus. The loading unit has a first holding portion for holding the wafer, and the unloading unit has a second holding portion for holding the wafer.

### BACKGROUND OF THE INVENTION

### Field of the Invention

The present invention relates to a grinding apparatus.

### Description of the Related Art

In the operation of a grinding apparatus, a robot is first operated to draw a wafer out of a cassette storing a plurality of wafers supported on shelves. Thereafter, the wafer is transferred to a temporary setting table by the robot and then positioned on the temporary setting table. Thereafter, loading means having a swing arm and a loading pad is operated to load the wafer from the temporary setting table to a chuck table having a holding surface for holding the wafer. Thereafter, the wafer held on the chuck table is ground by using a grinding wheel having abrasive members. Thereafter, a cleaning unit is operated to spray a two-component fluid composed of air and water toward the upper surface (work surface) of the wafer ground by the abrasive members of the grinding wheel, thereby cleaning the upper surface of the wafer. Thereafter, unloading means having a swing arm and an unloading pad is operated to unload the wafer from the chuck table to a spinner. Thereafter, the spinner is operated to rotate the wafer as supplying a cleaning water to the wafer, thereby cleaning the wafer and next drying it by using a centrifugal force. Thereafter, the robot is operated again to store the wafer into the cassette. Thus, a series of grinding operation for the wafer is finished.

The loading pad of the loading means has a holding surface for holding the upper surface of the wafer to be ground, and the lower surface of the wafer held on the holding surface of the loading pad is cleaned by a lower surface cleaning unit provided in a loading path where the loading means is moved (see Japanese Patent Laid-Open Nos. 2015-199158, 2011-018802, and 2010-094785, for example). Similarly, the unloading pad of the unloading means has a holding surface for holding the upper surface of the wafer ground, and the lower surface of the wafer held on the holding surface of the unloading pad is cleaned by another lower surface cleaning unit provided in an unloading path where the unloading means is moved. Further, the grinding apparatus includes an unloading pad cleaning unit for cleaning the holding surface of the unloading pad in the condition where the wafer is not held on the holding surface of the unloading pad, whereby the holding surface of the unloading pad is suitably cleaned.

The cleaning unit for cleaning the upper surface of the wafer ground includes a two-fluid cleaning portion for spraying the two-component fluid mentioned above to the holding surface of the chuck table or the upper surface of the wafer ground, thereby cleaning the holding surface of the chuck table or the upper surface of the wafer ground and also includes an abrasive cleaning portion having cleaning abrasive members adapted to come into contact with the holding surface of the chuck table, thereby scraping grinding dust off the holding surface of the chuck table. Thus, the holding surface of the chuck table is also cleaned by the cleaning unit.

### SUMMARY OF THE INVENTION

In the past, the cleaning unit has been provided with an elevating mechanism for vertically moving the cleaning unit in a large amount, so as to avoid the possibility that the cleaning unit may collide with the loading means for loading the wafer to the chuck table before grinding or the unloading means for unloading the wafer from the chuck table after grinding. However, when the two-fluid cleaning portion and the abrasive cleaning portion of the cleaning unit are being vertically moved by operating the elevating mechanism, the loading means and the unloading means must wait, causing a bottleneck in reducing the operation time required for grinding. That is, there is a problem such that the operation time for grinding is increased by the vertical movement of the cleaning unit. Further, when the loading means and the unloading means are waiting, it is desired that the wafer to be ground can be set on the temporary setting table and that the wafer ground can be cleaned by the spinner, thereby improving the productivity.

It is therefore an object of the present invention to provide a grinding apparatus which can eliminate the above problem due to the waiting of the loading means and the unloading means during the vertical movement of the two-fluid cleaning portion and the abrasive cleaning portion of the cleaning unit.

In accordance with an aspect of the present invention, there is provided a grinding apparatus for grinding a wafer having an upper surface and a lower surface, the grinding apparatus including a chuck table having a holding surface for holding the wafer; a grinding unit having a rotatable grinding wheel for grinding the wafer held on the holding surface of the chuck table, the grinding wheel having a plurality of abrasive members arranged annularly and adapted to come into contact with the upper surface of the wafer, whereby when the grinding wheel is rotated and the abrasive members come into contact with the upper surface of the wafer held on the holding surface of the chuck table, the upper surface of the wafer is ground by the abrasive members; loading means provided at one side portion of the grinding apparatus in a lateral direction thereof for loading the wafer to the chuck table before grinding; unloading means provided at the other side portion of the grinding apparatus in the lateral direction for unloading the wafer from the chuck table after grinding; a cleaning unit for cleaning the holding surface of the chuck table or the upper surface of the wafer held on the holding surface of the chuck table; and a control unit for controlling ail of the chuck table, the grinding unit, the loading means, the unloading means, and the cleaning unit; the loading means including a first holding portion for holding the wafer before grinding and first horizontal moving means for horizontally moving the first holding portion; the unloading means including a second holding portion for holding the wafer after grinding and second horizontal moving means for horizontally moving the second holding portion; the cleaning unit including a cleaning portion For clearing the holding surface of the chuck table or the upper surface of the wafer held on the holding surface of the chuck table and third horizontal moving means for horizontally moving the cleaning portion in the lateral direction; whereby when the wafer is unloaded from the holding surface of the chuck table by the unloading means after grinding, the third horizontal moving means is operated by the control unit to horizontally move the cleaning portion toward the first holding portion in a first direction, thereby allowing the unloading of the wafer from the holding surface of the chuck table by the unloading means after grinding; and when the wafer is loaded to the holding surface of the chuck table by the loading means before grinding, the third horizontal moving means is operated by the control unit to horizontally move the cleaning portion toward the second holding portion in a second direction opposite to the first direction, thereby allowing the loading of the wafer to the holding surface of the chuck table by the loading means before grinding.

Preferably, the grinding apparatus further includes a first lower surface cleaning unit for cleaning the lower surface of the wafer held by the first holding portion of the loading means before grinding; the first lower surface cleaning unit being located on a path of movement of the wafer by the loading means; whereby while the lower surface of the wafer is being cleaned by the first lower surface cleaning unit before grinding, the unloading of the wafer from the holding surface of the chuck table by the unloading means after grinding is allowed.

Preferably, the grinding apparatus further includes a second lower surface cleaning unit for cleaning the lower surface of the wafer held by the second holding portion of the unloading means after grinding; the second lower surface cleaning unit being located on a path of movement of the wafer by the unloading means; whereby while the lower surface of the wafer being cleaned by the second lower surface cleaning unit after grinding, the loading of the wafer to the holding surface of the chuck table by the loading means before grinding is allowed.

Preferably, the second holding portion of the unloading means has a holding surface for holding the upper surface of the wafer after grinding; the second lower surface cleaning unit including a holding surface cleaning portion for cleaning the holding surface of the second holding portion of the unloading means.

As described above, the cleaning portion is horizontally moved in the lateral direction of the grinding apparatus so as to avoid the collision with the loading means and the unloading means in loading and unloading the wafer. Accordingly, it is unnecessary to vertically move the cleaning portion, so as to ensure the path of movement of the wafer by the loading means and the unloading means, so that the time required for transfer of the wafer by the loading means and the unloading means can be reduced. Accordingly, the cleaning time can be extended. Further, a receptacle for receiving a cleaning water from the cleaning portion is not required.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a plan view depicting a grinding apparatus according to a preferred embodiment of the present invention;

FIG. 2A is a plan view depicting an operation of cleaning an upper surface (holding surface) of a chuck table by using a two-component fluid before loading a wafer to be ground;

FIG. 2B is a sectional view of the condition depicted in FIG. 2A as viewed from a rear side of the grinding apparatus;

FIG. 3A is a plan view depicting an operation of cleaning the upper surface of the chuck table by using cleaning abrasive members before loading the wafer;

FIG. 3B is a sectional view of the condition depicted in FIG. 3A as viewed from the rear side of the grinding apparatus;

FIG. 4A is a plan view depicting an operation of loading the wafer to the holding surface of the chuck table;

FIG. 4B is a sectional view of the condition depicted in FIG. 4A as viewed from the rear side of the grinding apparatus;

FIG. 5A is a plan view depicting an operation of cleaning the upper surface of another wafer previously ground as held on another chuck table;

FIG. 5B is a sectional view of the condition depicted in FIG. 5A as viewed from the rear side of the grinding apparatus;

FIG. 6A is a plan view depicting an operation of unloading the wafer from the holding surface of the chuck table after grinding;

FIG. 6B is a sectional view of the condition depicted in FIG. 6A as viewed from the rear side of the grinding apparatus;

FIG. 7A is a plan view depicting an operation of cleaning the holding surface of the chuck table after unloading the wafer ground;

FIG. 7B is a sectional view of the condition depicted in FIG. 7A as viewed from the rear side of the grinding apparatus;

FIG. 8A is a plan view depicting an operation of cleaning a lower surface of the wafer to be ground in a loading path and simultaneously unloading the wafer ground from the chuck table;

FIG. 8B is a sectional view of the condition depicted in FIG. 8A as viewed from the rear side of the grinding apparatus;

FIG. 9A is a plan view depicting an operation of cleaning the lower surface of the wafer ground in an unloading path and simultaneously loading the wafer to be ground to the chuck table; and

FIG. 9B is a sectional view of the condition depicted in FIG. 9A as viewed from the rear side of the grinding apparatus.

### DETAILED DESCRIPTION OF THE PREFERRED EMBODIMENT

1. Configuration of Grinding Apparatus

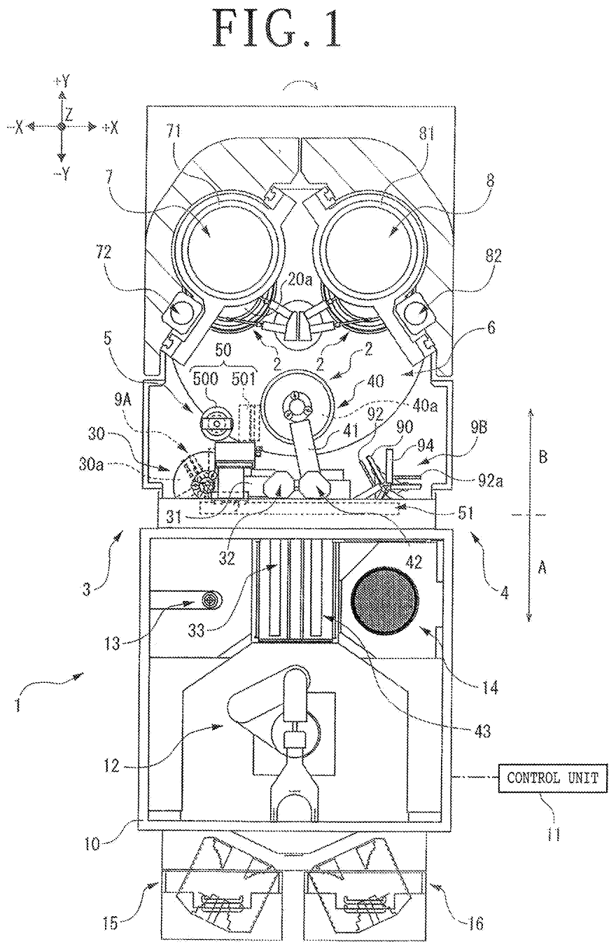

Referring to FIG. 1, there is depicted a grinding apparatus 1 in plan. The grinding apparatus 1 is an apparatus for grinding a wafer W as a plate-shaped semiconductor workpiece by using a first grinding unit 7 and a second grinding unit 8. The wafer W has an upper surface Wa and a lower surface Wb. The configuration of the grinding apparatus 1 will now be described. In the following description, the X direction includes the +X direction depicted by an arrow +X in the drawings and the −X direction depicted by an arrow −X in the drawings. Similarly, the Y direction includes the +Y direction depicted by an arrow −Y in the drawings and the −Y direction depicted by an arrow −Y in the drawings. Further, the Z direction includes the +Z direction depicted by an arrow in the drawings and the −Z direction depicted by an arrow −Z in the drawings. The X direction and the Y direction are perpendicular to each other to define a horizontal plane, and the Z direction is perpendicular to this horizontal plane.

As depicted in FIG. 1, the grinding apparatus 1 includes a base 10 having a substantially rectangular shape elongated in the Y direction. That is, a lateral direction of the grinding apparatus 1 is parallel to the X direction, and a longitudinal direction of the grinding apparatus 1 is parallel to the Y direction. A control unit 11 is connected to the grinding apparatus 1, and electrical signals are adapted to be transmitted from the control unit 11 to various mechanisms included in the grinding apparatus 1, thereby controlling the grinding apparatus 1. The upper surface of the base 10 in its front portion (in the −Y direction) is set as a standby area A where the wafer W is loaded or unloaded, and the upper surface of the base 10 at its rear portion (in the +Y direction) is set as a grinding area B where the wafer W is ground.

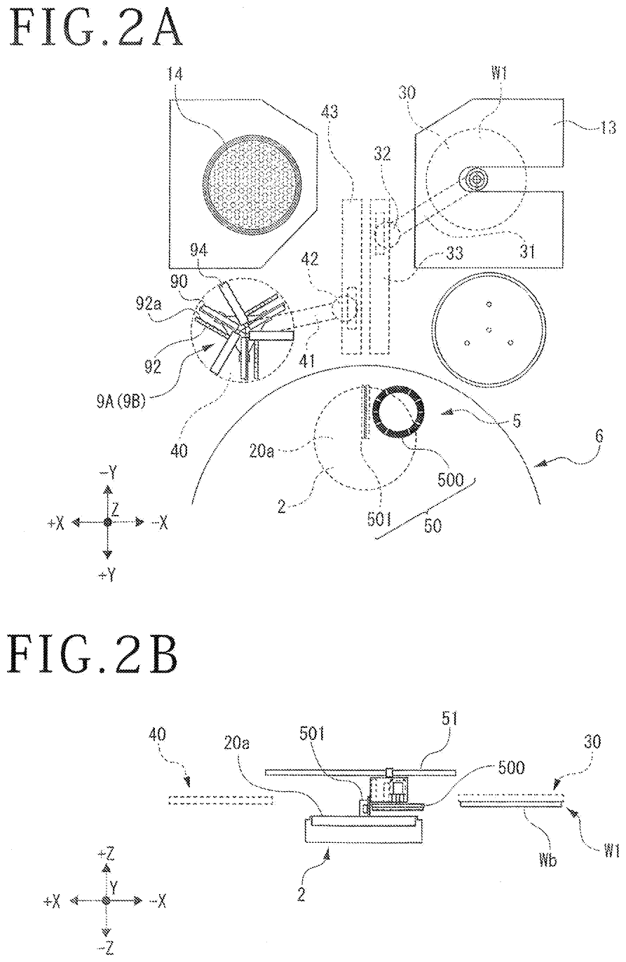

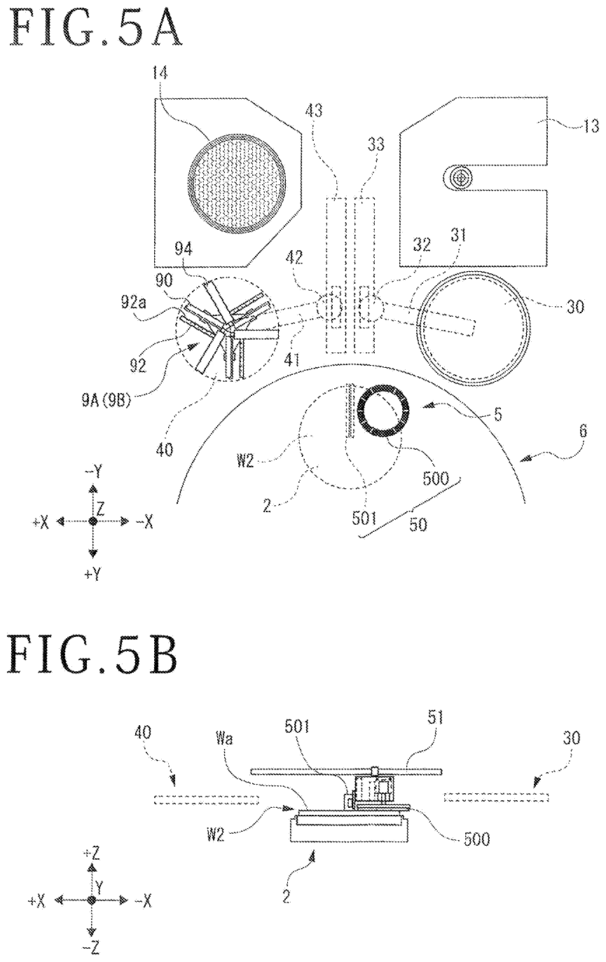

A first cassette 15 and a second cassette 16 are provided in the standby area A at the front end thereof. The first cassette 15 functions to store a plurality of wafers W1 before grinding, and the second cassette 16 functions to store a plurality of wafers W2 after grinding. That is, each wafer W1 (see FIG. 2A) is the wafer W to be ground by the first grinding unit 7 and the second grinding unit 8, and each wafer W2 (see FIG. 5A) is the wafer W ground by the first grinding unit 7 and the second grinding unit 8. A robot 12 is provided in the standby area A. The robot 12 functions to draw each wafer W1 out of the first cassette 15 before grinding and also to insert each wafer W2 into the second cassette 16 after grinding.

Further, a temporary setting table 13 is provided in the standby area A. The wafer W (wafer W1) drawn out of the first cassette 15 by the robot 12 is transferred to the temporary setting table 13 by the robot 12 and then placed in position on the temporary setting table 13.

In addition, a spinner 14 as a single-wafer cleaning mechanism for cleaning the wafer W (wafer W2) after grinding is also provided in the standby area A.

Further, loading means 3 and unloading means 4 are provided in an area between the standby area A and the grinding area B. The loading means 3 functions to transfer the wafer W (wafer W1) from the standby area A to the grinding area B before grinding. The unloading means 4 functions to transfer the wafer W (wafer W2) from the grinding area 3 to the standby area A after grinding.

The loading means 3 includes a first holding portion 30 for holding the wafer (wafer W1). The first holding portion 30 may be configured by a suction pad, Bernoulli pad, or edge clamp, for example. The loading means 3 further Includes a first arm 31 and first swinging means 32. The first arm 31 functions to support the first holding portion 30. The first swinging means 32 functions to horizontally swing the first arm 31. That is, one end of the first arm 31 is connected to the first holding portion 30, and the other end of the first arm 31 is connected to the first swinging means 32. Accordingly, when the first swinging means 32 is operated, the first arm 31 is horizontally rotated about the first swinging means 32, i.e., about a vertical axis parallel to the Z direction, so that the first holding portion 30 can be moved between the standby area A and the grinding area B. Further, the loading means 3 includes first horizontal moving means 33 having a rail extending in the Y direction between the standby area A and the grinding area B. The first, horizontal moving means 33 functions to horizontally move the first swinging means 32 in the Y direction. Accordingly, when the first swinging means 32 is horizontally moved in the Y direction by the first horizontal moving means 33, the first holding portion 30 can be horizontally moved In the Y direction.

The unloading means 4 is similar in configuration to the loading means 3. That is, the unloading means 4 includes a second holding portion 40 for holding the wafer W (wafer W2), a second arm 41 for supporting the second holding portion 40, second swinging means 42 for horizontally swinging the second arm 41, and second horizontal moving means 43 for horizontally moving the second swinging means 42 in the Y direction. Accordingly, when the second swinging means 42 is horizontally moved in the Y direction by the second horizontal moving means 43, the second holding portion 40 connected through the second arm 41 to the second swinging means 42 can be horizontally moved in the Y direction. The first holding portion 30 has a lower surface functioning as a holding surface for holding the wafer W (wafer W1) before grinding. Similarly, the second holding portion 40 has a lower surface functioning as a holding surface for holding the wafer W (wafer W2) after grinding. In particular, the holding surface of the second holding portion 40 is denoted by reference symbol 40a as depicted in FIG. 2B.

There are provided in the grinding area B three disk-shaped chuck tables 2 each for holding the wafer W and a disk-shaped turn table 6 for supporting these three disk-shaped chuck tables 2. The three chuck tables 2 have the same configuration. The three chuck tables 2 are provided on the turn table 6 so as to be arranged at equal intervals (at 120 degrees intervals) along the outer circumference of the turn table 6. Each chuck table 2 is rotatable by any rotating means (not depicted) about a vertical axis parallel to the Z direction, and this vertical axis passes through the center of the chuck table 2. Similarly, the turn table 6 is rotatable by any rotating means (not depicted) about a vertical axis parallel to the Z direction, and this vertical axis passes through the center oi the turn table 6. Accordingly, when the turn table 6 is rotated, the three chuck tables 2 are rotated together about the center of the turn table 6.

Each chuck table 2 is connected to suction means (not depicted) for applying a suction force to the chuck table 2. Each chuck table 2 has an upper surface functioning as a holding surface 20a for holding the wafer W under suction. Accordingly, when the suction means is operated, the suction force produced from the suction means is applied to the holding surface 20a of each chuck table 2, thereby holding the wafer W on the holding surface 20a under suction.

The first grinding unit 7 and the second grinding unit 8 for grinding the wafer W held on each chuck table 2 are provided in the grinding area 3 at its rear portion (in the +Y direction). The first grinding unit 7 includes a first grinding wheel 71 having a plurality of first abrasive members (not depicted) fixed at the lower end and arranged annularly along the outer circumference. The first grinding wheel 71 is rotatable about its vertical axis by any rotating means (not depicted). Further, the first grinding unit 7 includes a first elevating motor 72 for vertically moving the first grinding wheel 71 in the Z direction. Accordingly, when the first elevating motor 72 is operated, the first grinding wheel 71 can be vertically moved in the Z direction.

The second grinding unit 8 is similar in configuration to the first grinding unit 7. That is, the second grinding unit 8 includes a second grinding wheel 81 having a plurality of second abrasive members (not depicted) and further includes a second elevating motor 82 for vertically moving the second grinding wheel 81 in the Z direction. The second grinding wheel 81 is also rotatable about its vertical axis by any rotating means (not depicted), and the second abrasive members are fixed at the lower end of the second grinding wheel 81 so as to be arranged annularly along the outer circumference of the second grinding wheel 81. When the second elevating motor 82 is operated, the second grinding wheel 81 can be vertically moved in the Z direction.

Each second abrasive member in the second grinding unit 8 contains abrasive grains smaller in size than those contained in each first abrasive member in the first grinding unit 7. For example, the first grinding unit 7 having the first abrasive members containing relatively large-sized abrasive grains is used to perform coarse grinding for reducing a thickness of the wafer W, and the second grinding unit 8 having the second abrasive members containing abrasive grains smaller in size than those of the first abrasive members is used to perform finish grinding for smoothening the upper surface Wa of the wafer W after performing the above coarse grinding by the first grinding unit 7. However, the grinding unit in the grinding apparatus according to the present invention is not limited to the above configuration, but a single grinding unit may be provided in the grinding apparatus 1.

A cleaning unit 5 is further provided in the grinding area B. The cleaning unit 5 includes a cleaning portion 50 for cleaning the holding surface 20a of each chuck table 2 or the upper surface Wa of the wafer W (wafer W2) held on the holding surface 20a and also includes third horizontal moving means 51 for horizontally moving the cleaning portion 50 in the X direction as the lateral direction of the grinding apparatus 1. The cleaning portion 50 includes an abrasive cleaning portion 500 having cleaning abrasive members for cleaning and a two-fluid cleaning portion 501 for spraying a two-component fluid composed of cleaning water and air.

A first lower surface cleaning unit 9A for cleaning the lower surface Wb of the wafer W (wafer W1) held by the first holding portion 30 is provided on the path of movement of the loading means 3 in the grinding area 8. As depicted in FIG. 1, the first lower surface cleaning unit 9A includes three cleaning members 94 and three cleaning water nozzles 92 for respectively supplying a cleaning water to these three cleaning members 94. The three cleaning members 94 extend radially so as to be arranged at equal intervals (at 120 degrees intervals), and the three cleaning water nozzles 92 also extend radially so as to be arranged at equal intervals (at 120 degrees intervals). Each cleaning water nozzle 92 has a plurality of nozzle holes 92a for spraying the cleaning water.

Similarly, a second lower surface cleaning unit 9B for cleaning the lower surface Wb of the wafer W (wafer W2) held by the second holding portion 40 is provided on the path of movement of the unloading means 4 in the grinding area B. The second lower surface cleaning unit 9B is similar in configuration to the first lower surface cleaning unit 9A. In the second lower surface cleaning unit 9B, the same parts as those of the first lower surface cleaning unit 9A are denoted by the same reference symbols, and the description thereof will be omitted herein.

In addition, the second lower surface cleaning unit 9B is provided with a holding surface cleaning portion 90 for cleaning the holding surface 40a of the second holding portion 40. For example, the holding surface cleaning portion 90 may be configured by a brush in the form of tightly set bristles of chemical fiber, vegetable fiber, etc. or a stone formed from resin bonded abrasive, resin material, etc. The holding surface cleaning portion 90 is adapted to come into abutment against the holding surface 40a of the second holding portion 40, thereby cleaning the holding surface 40a.

The holding surface cleaning portion 90 and the cleaning members 94 are vertically movable. The vertical position of the holding surface cleaning portion SO is different from the vertical position of the cleaning members 94, and the relation in vertical position between the holding surface cleaning portion 90 and the cleaning members 94 can be inverted. More specifically, in cleaning the lower surface Wb of the wafer W by using the cleaning members 94, the cleaning members 94 are raised to a vertical position higher than that of the holding surface cleaning portion 90. Conversely, in cleaning the holding surface 40a of the second holding portion 40 by using the holding surface cleaning portion 90, the holding surface cleaning portion 90 is raised and the cleaning members 94 are lowered, so that the vertical position of the holding surface cleaning portion 90 becomes higher than the vertical position of the cleaning members 94.

2. Operation of Grinding Apparatus

There will now be described the operation of the grinding apparatus 1 in grinding the wafer W by using the grinding apparatus 1.

First, the wafer W1 stored in the first cassette 15 depicted in FIG. 1 is drawn out by the robot 12 and then placed on the temporary setting table 13 by the robot 12. During or before this operation, the third horizontal moving means 51 is operated to move the abrasive cleaning portion 500 and the two-fluid cleaning portion 501 In the X direction to the position above one of the three chuck tables 2 as depicted in FIGS. 2A and 2B, and the chuck table 2 is previously set at a standby position depicted in FIG. 2A. At this time, the two-fluid cleaning portion 501 is positioned near the center of the holding surface 20a of the chuck table 2. In this condition, the two-component fluid composed of water and air is sprayed from the two-fluid cleaning portion 501, thereby cleaning the holding surface 20a of the chuck table 2.

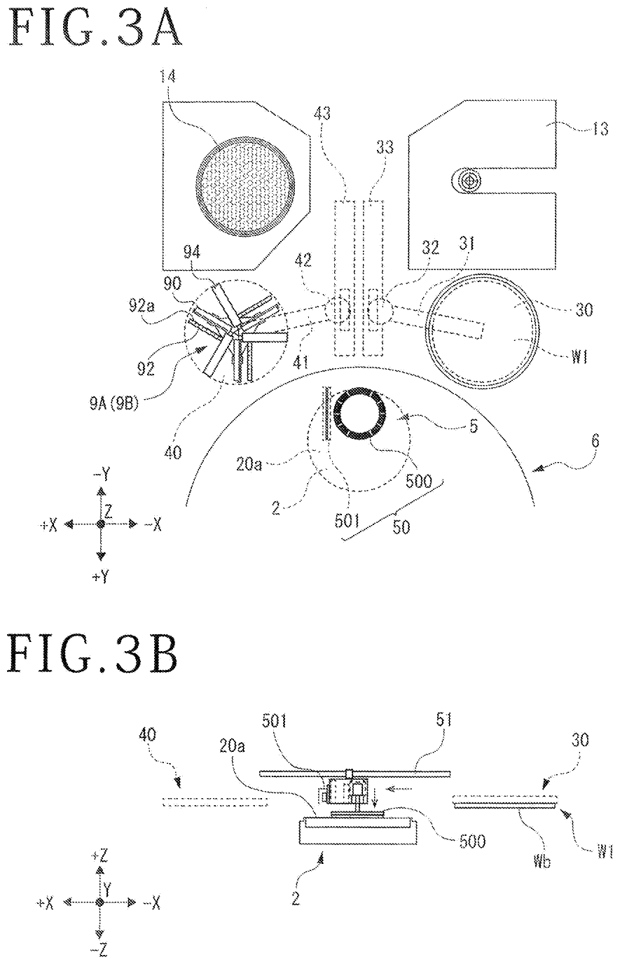

Thereafter, the third horizontal moving means 53 is operated again to move the abrasive cleaning portion 500 and the two-fluid cleaning portion 501 in the +X direction as depicted in FIGS. 3A and 3B, thereby positioning the abrasive cleaning portion 500 near the center of the holding surface 20a of the chuck table 2. Thereafter, the chuck table 2 is rotated and the abrasive cleaning portion 500 is lowered until the cleaning abrasive members of the abrasive cleaning portion 500 come into contact with the holding surface 20a of the chuck table 2, thereby cleaning the holding surface 20a of the chuck table 2. As a modification, the two-fluid cleaning for cleaning the holding surface 20a by using the two-fluid cleaning portion 501 as depicted in FIGS. 2A and 2B may be performed after performing the abrasive cleaning for cleaning the holding surface 20a by using the abrasive cleaning portion 500 as depicted in FIGS. 3A and 3B.

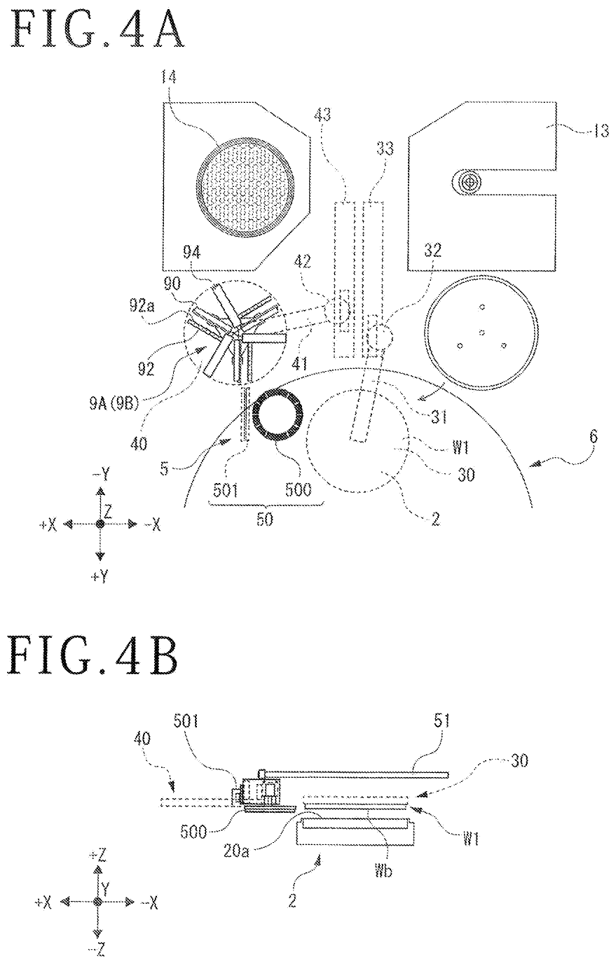

Thereafter, as depicted in FIGS. 4A and 4B, the third horizontal moving means 51 is operated again to move the cleaning portion 50 toward the second holding portion 40 in the +X direction (the second direction defined in the present invention). Thereafter, the first horizontal moving means 33 is operated to move the first swinging means 32 in the direction, and the first swinging means 32 is next operated to swing the first arm 31, thereby transferring the wafer Wi held by the first holding portion 30 from the temporary setting table 13 to the holding surface 20a of the chuck table 2. That is, the cleaning portion 50 is previously moved (retracted) from the chuck table 2 toward the second holding portion 40 in the +X direction (the second direction), so that the wafer W1 can be loaded to the holding surface 20a of the chuck table 2 by using the loading means 3.

Thereafter, as depicted in FIGS. 5A and 5B, the third horizontal moving means 51 is operated to move the cleaning portion 50 in the −X direction to the position above the holding surface 20a of the chuck table 2 on which the wafer W1 is held. Thereafter, the turn table 6 is rotated 120 degrees in the clockwise direction as viewed in plan, so that the wafer W2 ground by the second grinding unit 8 (see FIG. 1) is moved to the position near the standby area A as depicted in FIG. 5A. That is, another chuck table 2 holding the wafer W2 is moved from the grinding position below the second grinding unit 8 to the unloading position depicted in FIG. 5A. At the same time, the chuck table 2 holding the wafer W1 is moved from the loading position depicted in FIG. 4A to the position below the first grinding unit 7 (see FIG. 1). Thereafter, the two-component fluid is sprayed from the two-fluid cleaning portion 501 to the upper surface Ha of the wafer W2 ground, thereby cleaning the upper surface Wa of the wafer W2. Thereafter, the cleaning abrasive members of the abrasive cleaning portion 500 are brought into contact with the upper surface Wa of the wafer W2 to thereby clean the upper surface Wa of the wafer W2.

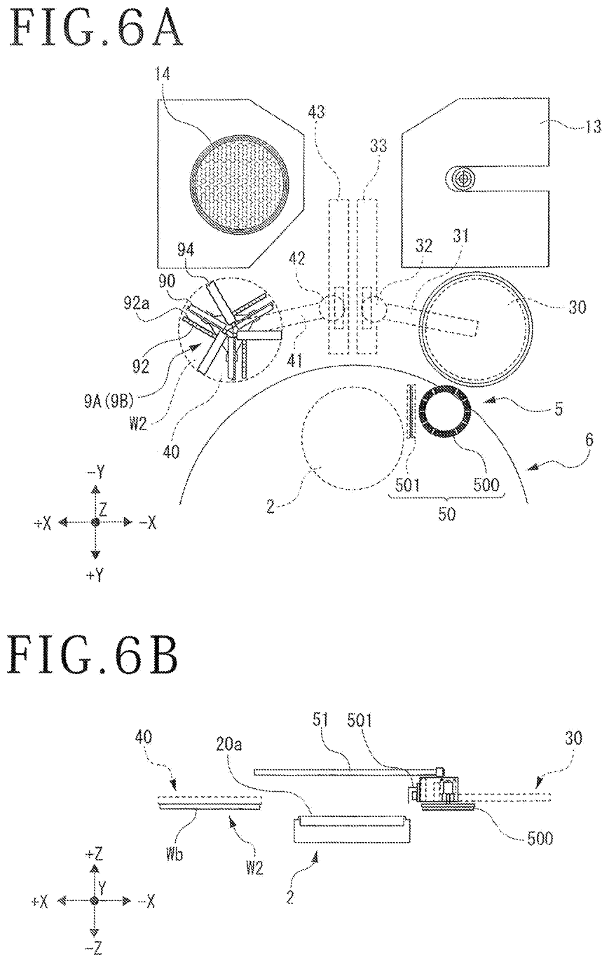

Thereafter, as depicted in FIGS. 6A and 6B, the third horizontal moving means 51 is operated again to move the cleaning portion 50 toward the first holding portion 30 in the −X direction (the first direction defined in the present invention). Thereafter, the wafer W2 is held by the second holding portion 40 and then unloaded from the chuck table 2 by the second holding portion 40. That is, the cleaning portion 50 is previously moved (retracted) from the chuck table 2 toward the first holding portion 30 in the −X direction (the first direction), so that the wafer W2 can be unleaded from the holding surface 20a of the chuck table 2 by using the unloading means 4.

As described above, the cleaning portion 50 is horizontally moved in the X direction by operating the third horizontal moving means 51, so that the path of movement of the loading means 3 and the path of movement of the unloading means 4 can be ensured. Accordingly, it is unnecessary to vertically move the first holding portion 30 and the second holding portion 40 in the Z direction. As a result, the waiting time required for the grinding apparatus 1 in the case of vertically moving the first holding portion 30 and the second holding portion 40 can be eliminated to thereby reduce the total operation time for grinding.

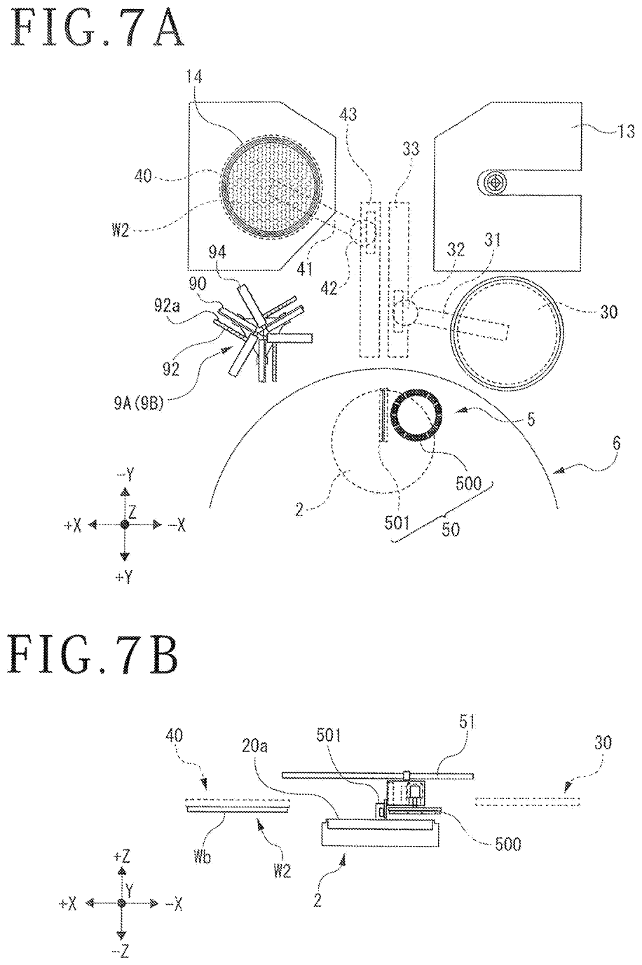

After holding the wafer W2 by using the second holding portion 40 of the unloading means 4 and then unloading the wafer W2 from the chuck table 2, the second holding portion 40 is moved to the spinner 14 by using the second swinging means 42 and the second horizontal moving means 43 as depicted in FIGS. 7A and 7B. Thus, the wafer W2 is held on the upper surface of the spinner 14, and the spinner 14 is next rotated to clean the wafer W2. At the same time, the cleaning portion 50 is moved in the +X direction to the position above the chuck table 2 by operating the third horizontal moving means 51 to clean the holding surface 20a of the chuck table 2. Thus, the cleaning of the wafer W2 by the spinner 14 and the cleaning of the holding surface 20a of the chuck table 2 by the cleaning portion 50 can be simultaneously performed.

As described above, the cleaning portion 50 is horizontally moved in the X direction by operating the third horizontal moving means 51 to thereby avoid the interference of the first holding portion 30 (or the second holding portion 40) and the cleaning portion 50. That is, it is possible to prevent that the cleaning portion 50 may collide with the first holding portion 30 (or the second holding portion 40). In the past, the cleaning portion 50 has been provides with a receptacle for receiving a cleaning water or waste liquid from the cleaning portion 50 to thereby prevent water splashes to the loading means 3 (or the unloading means 4). Meanwhile, according to the present invention, there is no timing of overlapping between the first holding portion 30 (or the second holding portion 40) and the cleaning portion 50 as viewed in plan. Accordingly, the receptacle for the cleaning portion 50 can be eliminated. As a result, a cost for the receptacle itself can be eliminated and the time required for treatment of the waste liquid stored in the receptacle can also be eliminated.

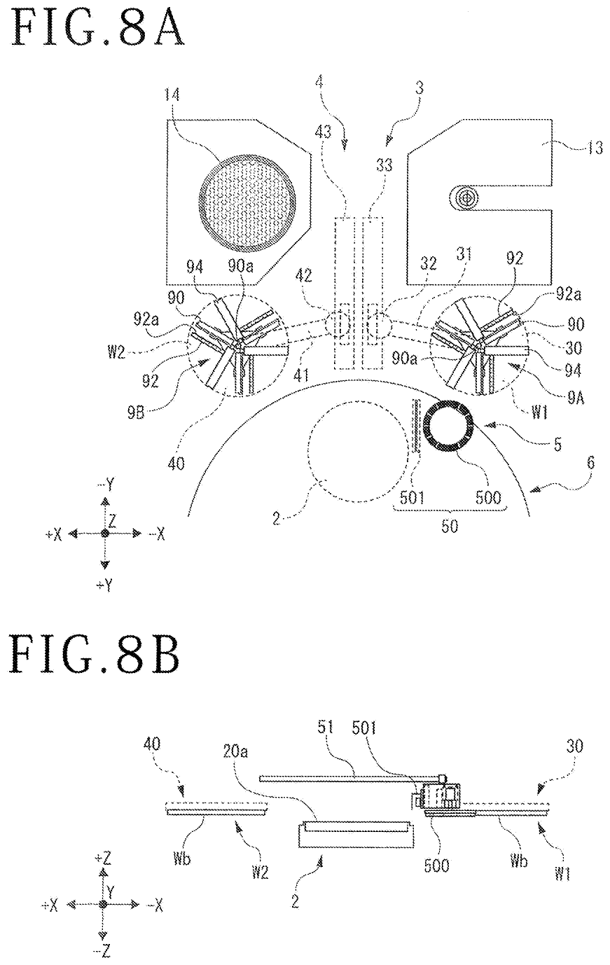

Further, the grinding apparatus 1 further includes the first lower surface cleaning unit 9A for cleaning the lower surface Wb of the wafer W1 held by the first holding portion 30. Accordingly, as depicted in FIGS. 8A and 8B, the lower surface Wb of the wafer W1 can be cleaned by the first lower surface cleaning unit 9A before moving the wafer W1 from the temporary setting table 13 to the chuck table 2. That is, the first lower surface cleaning unit 9A is located on the path of movement of the wafer W1 by the loading means 3. Accordingly, before placing the wafer W1 on the holding surface 20a of the chuck table 2, the wafer W1 held by the first holding portion 30 is positioned above the first lower surface cleaning unit 9A to thereby clean the lower surface Wb of the wafer W1. More specifically, a cleaning water is sprayed from the nozzle holes 92a of each cleaning water nozzle 92 in the first lower surface cleaning unit 9A and thereby supplied to the lower surface Wb of the wafer W1 held by the first holding portion 30. At the same time, each cleaning member 94 in the first lower surface cleaning unit 94 is brought into contact with the lower surface Wb of the wafer W1 as being rotated about a rotating shaft 90a by operating any rotating means (not depicted). Thus, the lower surface Wb of the wafer W1 can be cleaned by the first lower surface cleaning unit 9A. During this cleaning operation by the first lower surface cleaning unit 9A, the wafer W2 ground can be unloaded from the holding surface 20a of the chuck table 2 by using the unloading means 4. Accordingly, the time required for loading of the wafer W1 to the holding surface 20a and the time required for unloading of the wafer W2 from the holding surface 20a can be reduced to thereby improve the operation efficiency in grinding.

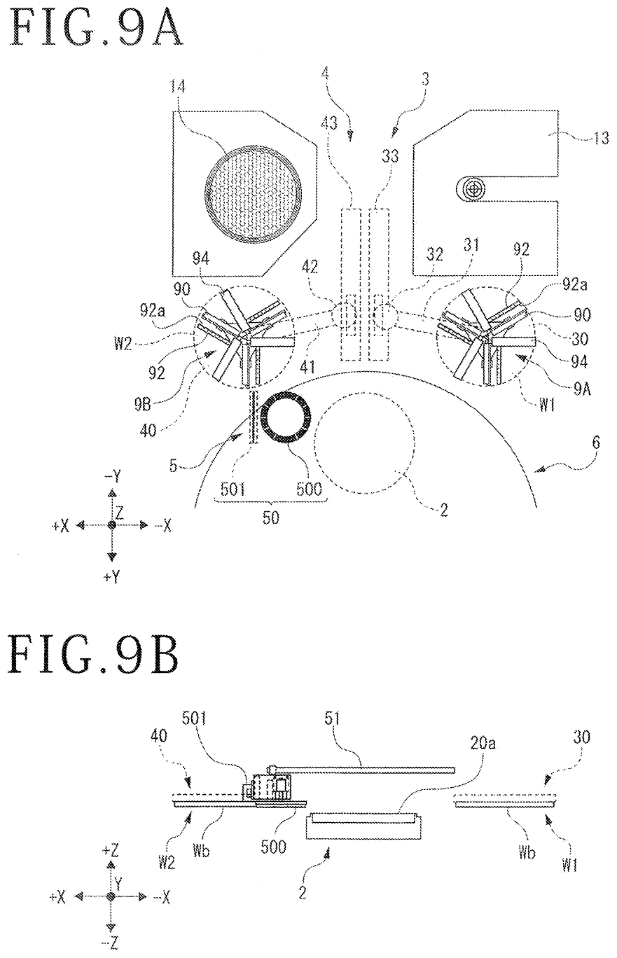

Similarly, the grinding apparatus 1 further includes the second lower surface cleaning unit 9B for cleaning the lower surface Wb of the wafer W2 held by the second holding portion 40. Accordingly, as depicted in FIGS. 9A and 9B, the lower surface Wb of the wafer W2 can be cleaned by the second lower surface cleaning unit 9B before moving the wafer W2 from the chuck table 2 to the spinner 14. That is, the second lower surface cleaning unit 9B is located on the path of movement of the wafer W2 by the unloading means 4. Accordingly, before placing the wafer W2 on the upper surface of the spinner 14, the wafer W2 held by the second holding portion 40 is positioned above the second lower surface cleaning unit 9B to thereby clean the lower surface Wb of the wafer W2. The cleaning operation by the second lower surface cleaning unit 9B is similar to that by the first lower surface cleaning unit 9A. During this cleaning operation by the second lower surface cleaning unit 9B, another wafer W1 can be loaded to the holding surface 20a of the chuck table 2 by using the loading means 3. Accordingly, the operation efficiency can be further improved.

In addition, the second lower surface cleaning unit 9B includes the holding surface cleaning portion 90 having resin bonded abrasive or the like for cleaning the holding surface 40a of the second holding portion 40. Accordingly, in the condition where the wafer W2 is not held by the second holding portion 40, the resin bonded abrasive of the holding surface cleaning portion 90 is brought into contact with the holding surface 40a of the second holding portion 40 as supplying a cleaning water from the cleaning water nozzles 92, thereby cleaning the holding surface 40a of the second holding portion 40. By cleaning the holding surface 40a to keep the condition that no foreign matter adheres to the holding surface 40a, there is no possibility that foreign matter may be caught between the holding surface 40a and the upper surface Wa of the wafer W2. Accordingly, there is no possibility of scratches on the upper surface Wa of the wafer W2 (the surface to be held on the holding surface 40a) due to the foreign matter. Further, it is possible to prevent that the wafer W2 held on the holding surface 40a may be damaged by the foreign matter.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A grinding apparatus for grinding a wafer having an upper surface and a lower surface, said grinding apparatus comprising:
a chuck table having a holding surface for holding said wafer;
a grinding unit having a rotatable grinding wheel for grinding said wafer held on the holding surface of said chuck table, said grinding wheel having a plurality of abrasive members arranged annularly and adapted to come into contact with the upper surface of said wafer, wherein when said grinding wheel is rotated and said abrasive members come into contact with the upper surface of said wafer held on the holding surface of said chuck table, the upper surface of said wafer is ground by said abrasive members;
loading means provided at one side portion of said grinding apparatus in a lateral direction thereof for loading said wafer to said chuck table before grinding;
unloading means provided at the other side portion of said grinding apparatus in said lateral direction for unloading said wafer from said chuck table after grinding;
a cleaning unit for cleaning the holding surface of said chuck table or the upper surface of said wafer held on the holding surface of said chuck table; and
a control unit for controlling all of said chuck table, said grinding unit, said loading means, said unloading means, and said cleaning unit;
said loading means including a first holding portion for holding said wafer before grinding and first horizontal moving means for horizontally moving said first holding portion;
said unloading means including a second holding portion for holding said wafer after grinding and second horizontal moving means for horizontally moving said second holding portion;
said cleaning unit including a cleaning portion for cleaning the holding surface of said chuck table or the upper surface of said wafer held on the holding surface of said chuck table and third horizontal moving means for horizontally moving said cleaning portion in said lateral direction;
wherein when said wafer is unloaded from the holding surface of said chuck table by said unloading means after grinding, said third horizontal moving means is operated by said control unit to horizontally move said cleaning portion toward said first holding portion in a first direction, thereby allowing the unloading of said wafer from the holding surface of said chuck table by said unloading means after grinding, and
when said wafer is loaded to the holding surface of said chuck table by said loading means before grinding, said third horizontal moving means is operated by said control unit to horizontally move said cleaning portion toward said second holding portion in a second direction opposite to said first direction, thereby allowing the loading of said wafer to the holding surface of said chuck table by said loading means before grinding.

2. The grinding apparatus according to claim 1, further comprising:
a first lower surface cleaning unit for cleaning the lower surface of said wafer held by said first holding portion of said loading means before grinding;
said first lower surface cleaning unit being located on a path of movement of said wafer by said loading means;
wherein while the lower surface of said wafer is being cleaned by said first lower surface cleaning unit before grinding, the unloading of said wafer from the holding surface of said chuck table by said unloading means after grinding is allowed.

3. The grinding apparatus according to claim 2, further comprising:
a second lover surface cleaning unit for cleaning the lower surface of said wafer held by said second holding portion of said unloading means after grinding;
said second lower surface cleaning unit being located on a path of movement of said wafer by said unloading means;
wherein while the lower surface of said wafer being cleaned by said second lower surface cleaning unit after grinding, the loading of said wafer to the holding surface of said chuck table by said loading means before grinding is allowed.

4. The grinding apparatus according to claim 3,
wherein said second holding portion of said unloading means has a holding surface for holding the upper surface of said wafer after grinding;
said second lower surface cleaning unit including a holding surface cleaning portion for cleaning the holding surface of said second holding portion of said unloading means.
